(19) United States
(12) Patent Application Publication
(10) Pub. No.: US 2025/0334614 A1
(43) Pub. Date: Oct. 30, 2025

(54) CURRENT SENSOR

(71) Applicant: Murata Manufacturing Co., Ltd., Nagaokakyo-shi (JP)

(72) Inventor: Daisuke NAKAMURA, Nagaokakyo-shi (JP)

(21) Appl. No.: 19/262,344

(22) Filed: Jul. 8, 2025

Related U.S. Application Data
(63) Continuation of application No. PCT/JP2024/007543, filed on Feb. 29, 2024.

(30) Foreign Application Priority Data
Mar. 7, 2023 (JP) 2023-034564

(51) Int. Cl. G01R 15/20; G01R 19/00; G01R 33/00; G01R 33/09

(52) U.S. Cl. CPC G01R 15/205; G01R 15/207; G01R 19/0092; G01R 33/0005; G01R 33/0035; G01R 33/098

(57) ABSTRACT

A current sensor is provided in which each of first, second and third magnetic detection elements are arranged such that each of sensitivity axes of the magnetic detection elements is orthogonal to a first magnetic field that is generated around a first busbar when a current flows in the first busbar. Where current values of currents flowing in the first busbar is I1, flowing in the second busbar is I2, flowing in the third busbar is I3, and output values of the first, second and third magnetic detection elements are V1, V2, and V3, respectively, and an output component caused by a uniform external magnetic field is Bex, the processing circuit calculates at least one of I1, I2, and I3 that satisfy corresponding relationships: I2∝(d−f)V1+(f−b)V2+(b−d)V3, I3∝(c−e)V1+(e−a)V2+(a−c)V3, and I1=−(I2+I3), from linear equations with three unknowns: V1=aI2+bI3+Bex, V2=cI2+dI3+Bex, and V3=eI2+fI3+Bex.

### CROSS REFERENCE TO RELATED APPLICATIONS

This application is a continuation of International Application No. PCT/JP2024/007543, filed Feb. 29, 2024, which claims priority to Japanese Patent Application No. 2023-034564, filed Mar. 7, 2023, the contents of each of which are hereby incorporated by reference in their entireties.

### TECHNICAL FIELD

The present disclosure relates generally to current sensors and current detection devices.

### BACKGROUND

Currently, an existing current detection device is described in Japanese Unexamined Patent Application Publication No. 2013-113631. The current detection device disclosed therein includes an electric conductor, a magnetic detection element, and a magnetic shielding body. The magnetic detection element is installed in the vicinity of the electric conductor in such a manner as to face a center part of the electric conductor in the width direction thereof. The magnetic shielding body is configured in such a way that a pair of identically dimensioned magnetic shields are symmetrically arranged to face each other, with the electric conductor interposed therebetween, so that the pair of magnetic shields sandwich the electric conductor from outside at both side edges of the electric conductor in the width direction thereof.

In the current detection device described in Japanese Unexamined Patent Application Publication No. 2013-113631, the effect of a magnetic field from an adjacent busbar is reduced by the magnetic shield. Thus, the configuration of this current detection device is complicated.

### SUMMARY OF THE INVENTION

In view of the foregoing issues, it is an object of the present disclosure to provide a current sensor configured to measure current values of currents flowing in respective busbars of three busbars, in which three-phase AC currents flow, while suppressing the effect of an external magnetic field using a simple configuration that does not use any magnetic shield.

Thus, in an exemplary aspect, a current sensor is provided that includes three busbars, a first magnetic detection element, a second magnetic detection element, a third magnetic detection element, and a processing circuit. The three busbars are composed of a first busbar, a second busbar, and a third busbar, in which three-phase AC currents flow. The first magnetic detection element, the second magnetic detection element, and the third magnetic detection element are arranged relative to the three busbars with gaps therebetween. The processing circuit is electrically connected to each of the first magnetic detection element, the second magnetic detection element, and the third magnetic detection element and is configured to process a detection signal from each of the first, second and third magnetic detection elements. Sensitivity axes of the first magnetic detection element, the second magnetic detection element, and the third magnetic detection element are parallel to one another. Each of the first, second and third magnetic detection elements is arranged in such a way that each of the sensitivity axes is orthogonal to a first magnetic field that is generated around the first busbar when a current flows in the first busbar. Where a current value of a current flowing in the first busbar is I1, a current value of a current flowing in the second busbar is I2, a current value of a current flowing in the third busbar is I3, an output value of the first magnetic detection element is V1, an output value of the second magnetic detection element is V2, an output value of the third magnetic detection element is V3, and an output component caused by a uniform external magnetic field is Bex, the processing circuit is configured to calculate at least one of I1, I2, and I3 that satisfy corresponding relationships: I2∝(d−f)V1+(f−b)V2+(b−d)V3, I3∝(c−e)V1+(e−a)V2+(a−c)V3, and I1=−(I2+I3), from linear equations with three unknowns: V1=aI2+bI3+Bex, V2=cI2+dI3+Bex, and V3=eI2+fI3+Bex.

According to the exemplary aspects of the present disclosure, the current values of the currents flowing in the respective busbars can be measured in which the three-phase AC currents flow, while the effect of an external magnetic field can be suppressed using the simple configuration that does not use any magnetic shield.

### BRIEF DESCRIPTION OF DRAWINGS

FIG. 1 is a cross-sectional diagram illustrating a configuration of a current sensor according to Embodiment 1 of an exemplary aspect.

FIG. 2 is a perspective view illustrating a mounting structure of the current sensor according to Embodiment 1 of the exemplary aspect.

FIG. 3 is a circuit diagram illustrating a circuit configuration of a first magnetic detection element, a second magnetic detection element, a third magnetic detection element, and a processing circuit of the current sensor according to Embodiment 1 of the exemplary aspect.

FIG. 4 is a flowchart illustrating a method of determining coefficients a to f at the time of calibration of the current sensor according to an exemplary aspect.

FIG. 5 is a cross-sectional diagram illustrating a configuration of a current sensor according to Embodiment 2 of an exemplary aspect.

FIG. 6 is a cross-sectional diagram illustrating a configuration of a current sensor according to a modified example of Embodiment 2 of an exemplary aspect.

### DETAILED DESCRIPTION OF EMBODIMENTS

Next, current sensors according to exemplary embodiments of the present disclosure will be described with reference to drawings. It is noted that in the description of embodiments below, the same reference numerals are assigned to the same or corresponding portions of the drawings, and the description thereof will not be repeated.

### Embodiment 1

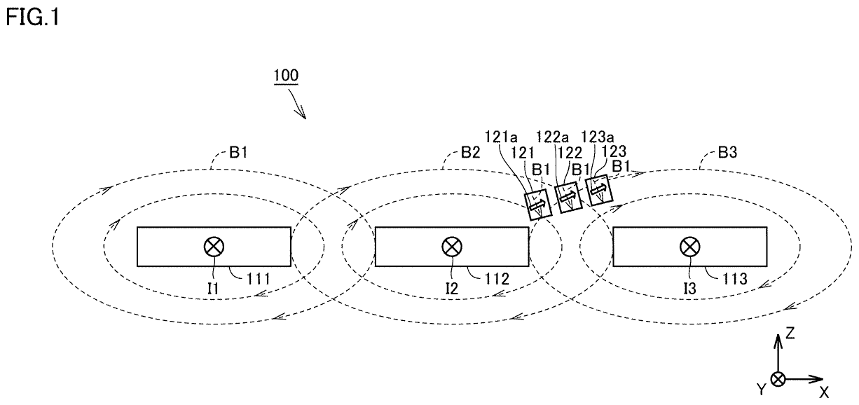

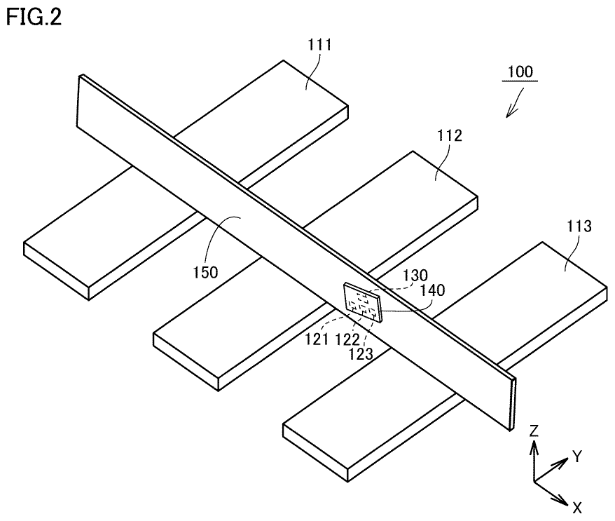

FIG. 1 is a cross-sectional diagram illustrating the configuration of a current sensor according to Embodiment 1 of an exemplary aspect of the present disclosure. FIG. 2 is a perspective view illustrating a mounting structure of the current sensor according to Embodiment 1. As illustrated in FIG. 1 and FIG. 2, a current sensor 100 according to Embodiment 1 includes three busbars, a first magnetic detection element 121, a second magnetic detection element 122, a third magnetic detection element 123, and a processing circuit 130.

In the present embodiment, the first magnetic detection element 121, the second magnetic detection element 122, and the third magnetic detection element 123 are mounted on a single chip 140. However, the first magnetic detection element 121, the second magnetic detection element 122, and the third magnetic detection element 123 may alternatively be mounted on separate chips in an exemplary aspect. The processing circuit 130 is mounted on the chip 140. The chip 140 is mounted on a board 150. The board 150 is arranged on the three busbars.

The three busbars are composed of a first busbar 111, a second busbar 112, and a third busbar 113, in which three-phase AC currents flow. The first busbar 111, the second busbar 112, and the third busbar 113 are busbars of a three-phase three-wire system in an exemplary aspect. In principle, AC currents with the same amplitude and different phases, each of which is shifted relative to the other by 120 degrees, are applied to the three busbars. For example, an AC current I1 of U-phase flows in the first busbar 111, an AC current I2 of V-phase flows in the second busbar 112, and an AC current I3 of W-phase flows in the third busbar 113. As a result, a first magnetic field B1 is generated around the first busbar 111, a second magnetic field B2 is generated around the second busbar 112, and a third magnetic field B3 is generated around the third busbar 113.

In the present embodiment, the first busbar 111, the second busbar 112, and the third busbar 113 are arranged side by side in a first direction (X-axis direction) with gaps therebetween. The first busbar 111, the second busbar 112, and the third busbar 113 are arranged in such a manner as to be positioned along the first direction (X-axis direction) in this order. However, the arrangement of the first busbar 111, the second busbar 112, and the third busbar 113 is not limited to this exemplary configuration.

The first magnetic detection element 121, the second magnetic detection element 122, and the third magnetic detection element 123 are arranged relative to the three busbars with gaps therebetween. The first magnetic detection element 121, the second magnetic detection element 122, and the third magnetic detection element 123 are arranged along a virtual plane (XZ plane) orthogonal to the three busbars while extending in the first direction (X-axis direction) and a second direction (Z-axis direction) that is orthogonal to the first direction (X-axis direction). Furthermore, the first magnetic detection element 121, the second magnetic detection element 122, and the third magnetic detection element 123 are arranged in such a manner as to be positioned along a direction that crosses both the first direction (X-axis direction) and the second direction (Z-axis direction).

The first magnetic detection element 121 has a sensitivity axis 121a. The second magnetic detection element 122 has a sensitivity axis 122a. The third magnetic detection element 123 has a sensitivity axis 123a. The sensitivity axis 121a of the first magnetic detection element 121, the sensitivity axis 122a of the second magnetic detection element 122, and the sensitivity axis 123a of the third magnetic detection element 123 are parallel to each other. The sensitivity axis 121a of the first magnetic detection element 121, the sensitivity axis 122a of the second magnetic detection element 122, and the sensitivity axis 123a of the third magnetic detection element 123 face the same direction.

Each of the first magnetic detection element 121, the second magnetic detection element 122, and the third magnetic detection element 123 has an odd function input-output characteristic in which a positive value is output when the magnetic detection element detects a magnetic field component facing one direction of the sensitivity axis direction and a negative value is output when the magnetic detection element detects a magnetic field component facing the other direction of the sensitivity axis direction.

Each of the first magnetic detection element 121, the second magnetic detection element 122, and the third magnetic detection element 123 is arranged in such a way that each of the sensitivity axis 121a of the first magnetic detection element 121, the sensitivity axis 122a of the second magnetic detection element 122, and the sensitivity axis 123a of the third magnetic detection element 123 is orthogonal to the first magnetic field B1 generated around the first busbar 111 when the AC current I1 flows in the first busbar 111.

According to this arrangement, the first magnetic field B1 causes each of the first magnetic detection element 121, the second magnetic detection element 122, and the third magnetic detection element 123 to output a value of zero. That is to say, the effects of the first magnetic field B1, which is generated by the current I1 flowing in the first busbar 111, on the first magnetic detection element 121, the second magnetic detection element 122, and the third magnetic detection element 123 are cancelled.

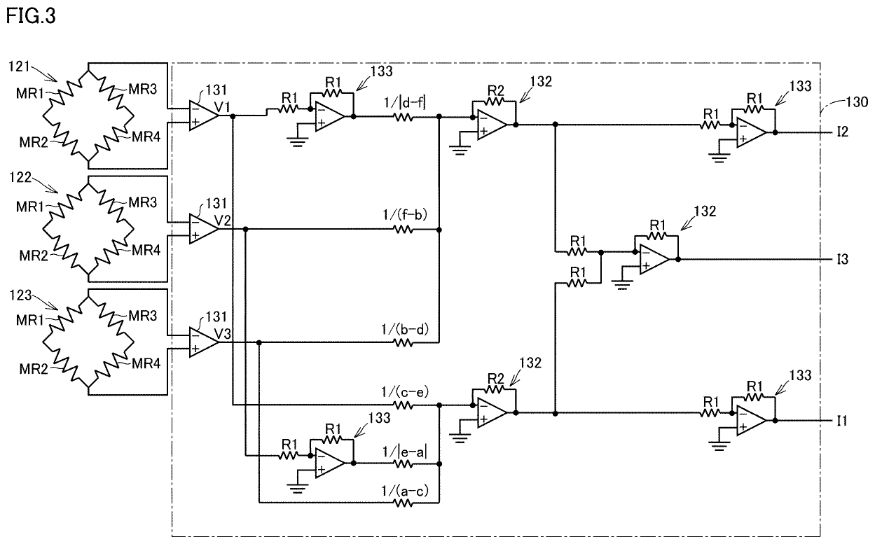

FIG. 3 is a circuit diagram illustrating the circuit configuration of the first magnetic detection element, the second magnetic detection element, the third magnetic detection element, and the processing circuit of the current sensor according to Embodiment 1. As illustrated in FIG. 3, each of the first magnetic detection element 121, the second magnetic detection element 122, and the third magnetic detection element 123 has a bridge circuit of Wheatstone bridge type, which is made up of four TMR (Tunnel Magneto Resistance) elements. It is also noted that each of the first magnetic detection element 121, the second magnetic detection element 122, and the third magnetic detection element 123 may have a bridge circuit made up of magnetic resistance elements such as GMR (Giant Magneto Resistance) elements, AMR (Anisotropic Magneto Resistance) elements, or the like, instead of the TMR elements. Further, each of the first magnetic detection element 121, the second magnetic detection element 122, and the third magnetic detection element 123 may alternatively have a half bridge circuit made up of two magnetic resistance elements in another exemplary aspect.

The processing circuit 130 is electrically connected to each of the first magnetic detection element 121, the second magnetic detection element 122, and the third magnetic detection element 123, and is configured to process a detection signal from each of the first magnetic detection element 121, the second magnetic detection element 122, and the third magnetic detection element 123.

In the present embodiment, the processing circuit 130 includes three differential amplifier circuits 131, which are respectively connected to the first magnetic detection element 121, the second magnetic detection element 122, and the third magnetic detection element 123, three inverting summing amplifier circuits 132, and four inverting amplifier circuits 133. It is also noted that the circuit configuration of the processing circuit 130 may be adjusted as required, depending on the spatial relationship among the first magnetic detection element 121, the second magnetic detection element 122, and the third magnetic detection element 123.

According to the exemplary aspect, when the current value of the current flowing in the first busbar 111 is defined as I1, the current value of the current flowing in the second busbar 112 is defined as I2, the current value of the current flowing in the third busbar 113 is defined as I3, the output value of the first magnetic detection element 121 is defined as V1, the output value of the second magnetic detection element 122 is defined as V2, the output value of the third magnetic detection element 123 is defined as V3, and an output component caused by a uniform external magnetic field is defined as Bex, the processing circuit 130 is configured to calculate at least one of I1, I2, and I3 that satisfy corresponding relationships: I2∝(d−f)V1+(f−b)V2+(b−d)V3, I3∝(c−e)V1+(e−a)V2+(a−c)V3, and I1=−(I2+I3), from linear equations with three unknowns: V1=aI2+bI3+Bex, V2=cI2+dI3+Bex, and V3=eI2+fI3+Bex.

Specifically, the processing circuit 130 stores therein, in advance, the linear equations with three unknowns: V1=aI2+bI3+Bex, V2=cI2+dI3+Bex, and V3=eI2+fI3+Bex. Thus, by determining the coefficients a to f at the time of calibration of the current sensor 100, the processing circuit 130 is configured to calculate each of the current value I1 of the current flowing in the first busbar 111, the current value I2 of the current flowing in the second busbar 112, and the current value I3 of the current flowing in the third busbar 113.

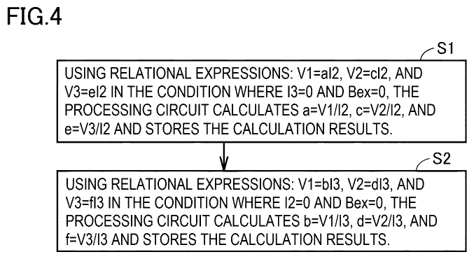

FIG. 4 is a flowchart illustrating a method of determining the coefficients a to f at the time of calibration of the current sensor. The calibration of the current sensor 100 is performed in the condition where no uniform external magnetic field is applied to each of the first magnetic detection element 121, the second magnetic detection element 122, and the third magnetic detection element 123. First, the calibration of the current sensor 100 is performed on the basis of the output of each of the first magnetic detection element 121, the second magnetic detection element 122, and the third magnetic detection element 123 at the time when I3=0 while the three-phase AC currents are flowing in the three busbars. That is to say, the first half of the calibration of the current sensor 100 is performed in the condition where I3=0 and Bex=0 in the exemplary aspect.

As a result, as illustrated in FIG. 4, by substituting zero for both I3 and Bex in the linear equations with three unknowns: V1=aI2+bI3+Bex, V2=cI2+dI3+Bex, and V3=eI2+fI3+Bex, the processing circuit 130 calculates a=V1/I2, c=V2/I2, and e=V3/I2 using relational expressions: V1=aI2, V2=cI2, and V3=eI2, and then stores the calculation results (Step S1).

Next, in the exemplary aspect, the calibration of the current sensor 100 can be performed on the basis of the output of each of the first magnetic detection element 121, the second magnetic detection element 122, and the third magnetic detection element 123 at the time when I2=0 while the three-phase AC currents are flowing in the three busbars. That is to say, the latter half of the calibration of the current sensor 100 is performed in the condition where I2=0 and Bex=0.

As a result, as illustrated in FIG. 4, by substituting zero for both I2 and Bex in the linear equations with three unknowns: V1=aI2+bI3+Bex, V2=cI2+dI3+Bex, and V3=eI2+fI3+Bex, the processing circuit 130 calculates b=V1/I3, d=V2/I3, and f=V3/I3 using relational expressions: V1=bI3, V2=dI3, and V3=fI3, and then stores the calculation results (Step S2).

By determining the coefficients a to f in the manner described above, the processing circuit 130 can be configured to calculate the current value I2 of the current flowing in the second busbar 112 that satisfies the relationship I2∝(d−f)V1+(f−b)V2+(b−d)V3, on the basis of the output value V1 of the first magnetic detection element 121, the output value V2 of the second magnetic detection element 122, and the output value V3 of the third magnetic detection element 123 in the condition where the three-phase AC currents are flowing in the three busbars. As described above, the current value I2 can be calculated with a high degree of accuracy by arithmetically removing the effects of the current value I3 and the output component Bex caused by the uniform external magnetic field while suppressing the effect of the current value I1 using the spatial relationship among the first magnetic detection element 121, the second magnetic detection element 122, the third magnetic detection element 123, and the three busbars.

Similarly, the processing circuit 130 can calculate the current value I3 of the current flowing in the third busbar 113 that satisfies the relationship I3∝(c−e)V1+(e−a)V2+(a−c)V3, on the basis of the output value V1 of the first magnetic detection element 121, the output value V2 of the second magnetic detection element 122, and the output value V3 of the third magnetic detection element 123 in the condition where the three-phase AC currents are flowing in the three busbars. As described above, the current value I2 can be calculated with a high degree of accuracy by arithmetically removing the effects of the current value I3 and the output component Bex caused by the uniform external magnetic field while suppressing the effect of the current value I1 using the spatial relationship among the first magnetic detection element 121, the second magnetic detection element 122, the third magnetic detection element 123, and the three busbars.

For the three-phase AC currents, in principle, the relationship I1+I2+I3=0 holds. Thus, from the relational expression I1=−(I2+I3), the processing circuit 130 can be configured to calculate the current value I1 of the current flowing in the first busbar 111.

As described above, based on the output value V1 of the first magnetic detection element 121, the output value V2 of the second magnetic detection element 122, and the output value V3 of the third magnetic detection element 123, the current sensor 100 according to the present embodiment can be configured to measure the current value of the current that flows in at least one or each of the three busbars, in which the three-phase AC currents flow, while suppressing the effect of an external magnetic field, using a simple configuration that does not use any magnetic shield. Thus, it is noted that the current sensor 100 does not necessarily calculate all of the current values I1 to I3 and instead can be configured to calculate at least one of the current values I1 to I3. The current sensor 100 retains the coefficients a to f, which are determined at the time of the calibration, and calculates the current values I1 to I3 using these coefficients a to f. Thus, the current sensor 100 can keep short-period responsiveness.

The current sensor 100 according to the present embodiment is a coreless current sensor that is not a current transformer, a contactless current sensor that is not a built-in busbar type current sensor, and a shield-less current sensor in which no magnetic shield is arranged between adjacent busbars. Because of this, the configuration of the current sensor 100 can be simplified and the current sensor 100 can be easily assembled while reducing the size and weight thereof.

In the current sensor 100 according to Embodiment 1 of the exemplary aspect, the first magnetic detection element 121, the second magnetic detection element 122, and the third magnetic detection element 123 are mounted on the single chip 140. This enables the current sensor 100 to have a simple configuration and to be assembled easily while reducing the size and weight thereof.

In the current sensor 100 according to Embodiment 1 of the exemplary aspect, the processing circuit 130 is mounted on the chip 140. This enables the current sensor 100 to have a simple configuration and to be assembled easily while reducing the size and weight thereof.

In the current sensor 100 according to Embodiment 1 of the exemplary aspect, the first busbar 111, the second busbar 112, and the third busbar 113 are arranged side by side in the first direction (X-axis direction) with gaps therebetween. Because of this configuration, by arranging the board 150, on which the chip 140 is mounted, on the three busbars, the first magnetic detection element 121, the second magnetic detection element 122, and the third magnetic detection element 123 can be easily arranged relative to the three busbars.

In the current sensor 100 according to Embodiment 1 of the exemplary aspect, the first magnetic detection element 121, the second magnetic detection element 122, and the third magnetic detection element 123 are arranged along a virtual plane (XZ plane) orthogonal to the three busbars while extending in the first direction (X-axis direction) and a second direction (Z-axis direction) that is orthogonal to the first direction (X-axis direction). This configuration enables the application of a measuring magnetic field in an in-plane direction of the magnetic resistance element such as a TMR element, a GMR element, an AMR element, or the like, which makes up the first magnetic detection element 121, the second magnetic detection element 122, and the third magnetic detection element 123. Thus, it becomes possible to increase the measurement accuracy of the current sensor 100.

It is noted that according to an exemplary aspect, the processing circuit 130 may have redundancy of capability that allows the processing circuit 130 to be switched to a circuit that can be configured to calculate at least one of the current values I1 to I3 by solving linear equations with two unknowns whose two variables are two current values of currents that can generate magnetic field components along which two working magnetic detection elements have sensitivity in a case where one of the first magnetic detection element 121, the second magnetic detection element 122, and the third magnetic detection element 123 fails.

### Embodiment 2

Next, a current sensor according to Embodiment 2 of an exemplary aspect of the present disclosure will be described with reference to drawings. It is noted that the current sensor according to Embodiment 2 is different from the current sensor according to Embodiment 1 in the order of sequence of the three busbars and the arrangement of the first magnetic detection element, the second magnetic detection element, and the third magnetic detection element. Thus, the description regarding the configuration similar to that of the current sensor according to Embodiment 1 will not be repeated.

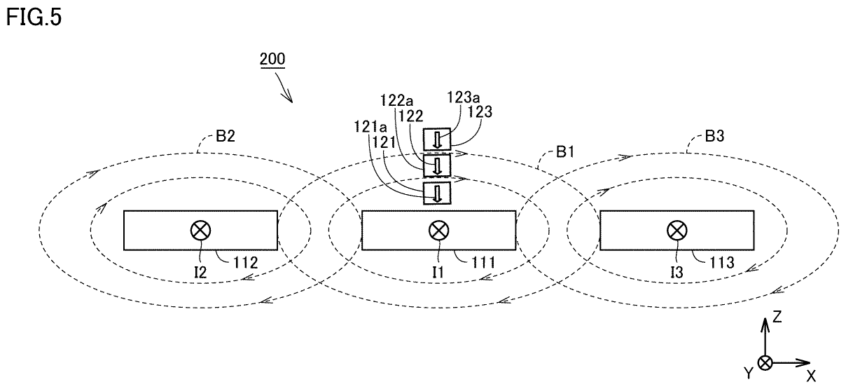

FIG. 5 is a cross-sectional diagram illustrating the configuration of a current sensor according to Embodiment 2 of an exemplary aspect. As illustrated in FIG. 5, in a current sensor 200 according to Embodiment 2, the second busbar 112, the first busbar 111, and the third busbar 113 are arranged in such a manner as to be positioned along the first direction (X-axis direction) in this order.

The first magnetic detection element 121, the second magnetic detection element 122, and the third magnetic detection element 123 are positioned along the second direction (Z-axis direction) and are located directly above the first busbar 111. Each of the first magnetic detection element 121, the second magnetic detection element 122, and the third magnetic detection element 123 is arranged in such a way that each of the sensitivity axis 121a of the first magnetic detection element 121, the sensitivity axis 122a of the second magnetic detection element 122, and the sensitivity axis 123a of the third magnetic detection element 123 is orthogonal to the first magnetic field B1 generated around the first busbar 111 when the AC current I1 flows in the first busbar 111. Specifically, each of the sensitivity axis 121a of the first magnetic detection element 121, the sensitivity axis 122a of the second magnetic detection element 122, and the sensitivity axis 123a of the third magnetic detection element 123 faces the second direction (Z-axis direction).

The current sensor 200 according to Embodiment 2 of the exemplary aspect can also be configured to measure the current value of the current that flows in each of the three busbars, in which the three-phase AC currents flow, while suppressing the effect of an external magnetic field, using a simple configuration that does not use any magnetic shield on the basis of the output value V1 of the first magnetic detection element 121, the output value V2 of the second magnetic detection element 122, and the output value V3 of the third magnetic detection element 123.

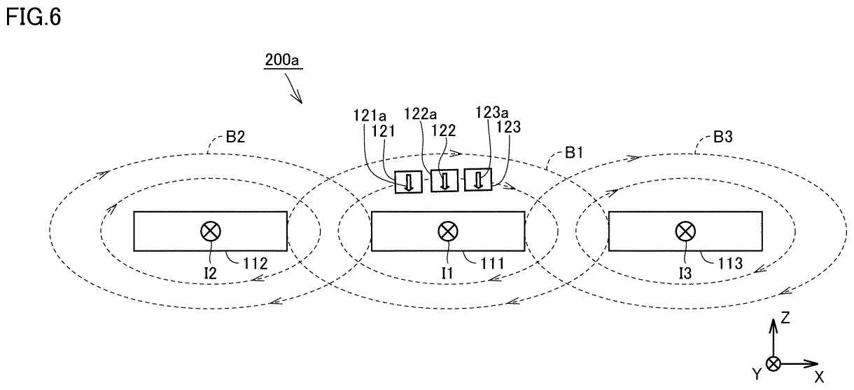

FIG. 6 is a cross-sectional diagram illustrating the configuration of a current sensor according to a modified example of Embodiment 2 of the exemplary aspect. As illustrated in FIG. 6, in a current sensor 200a according to a modified example of Embodiment 2 of the exemplary aspect, the first magnetic detection element 121, the second magnetic detection element 122, and the third magnetic detection element 123 are positioned along the first direction (X-axis direction) and are located directly above the first busbar 111. Each of the first magnetic detection element 121, the second magnetic detection element 122, and the third magnetic detection element 123 is arranged in such a way that each of the sensitivity axis 121a of the first magnetic detection element 121, the sensitivity axis 122a of the second magnetic detection element 122, and the sensitivity axis 123a of the third magnetic detection element 123 is orthogonal to the first magnetic field B1 generated around the first busbar 111 when the AC current I1 flows in the first busbar 111. Specifically, each of the sensitivity axis 121a of the first magnetic detection element 121, the sensitivity axis 122a of the second magnetic detection element 122, and the sensitivity axis 123a of the third magnetic detection element 123 faces the second direction (Z-axis direction).

The current sensor 200a according to the modified example of Embodiment 2 of the exemplary aspect can also measure the current value of the current that flows in each of the three busbars, in which the three-phase AC currents flow, while suppressing the effect of an external magnetic field, using a simple configuration that does not use any magnetic shield, on the basis of the output value V1 of the first magnetic detection element 121, the output value V2 of the second magnetic detection element 122, and the output value V3 of the third magnetic detection element 123.

In general, it is noted that in the description of the exemplary embodiments described above, combinable constituent elements of different embodiments may be combined as would be appreciated to one skilled in the art.

### REFERENCE SIGNS LIST

100, 200, 200a Current sensor
111 First busbar
112 Second busbar
113 Third busbar
121 First magnetic detection element
121a, 122a, 123a Sensitivity axis
122 Second magnetic detection element
123 Third magnetic detection element
130 Processing circuit
131 Differential amplifier circuit
132 Inverting summing amplifier circuit
133 Inverting amplifier circuit
140 Chip
150 Board

1. A current sensor comprising:
a first busbar, a second busbar, and a third busbar;
a first magnetic detection element, a second magnetic detection element, and a third magnetic detection element that are arranged relative to the first, second and third busbars with gaps therebetween; and
a processing circuit that is electrically connected to each of the first magnetic detection element, the second magnetic detection element, and the third magnetic detection element, and is configured to process a detection signal from each of the first magnetic detection element, the second magnetic detection element, and the third magnetic detection element,
wherein sensitivity axes of the first magnetic detection element, the second magnetic detection element, and the third magnetic detection element are parallel to one another,
wherein each of the first, second and third magnetic detection elements is arranged such that each of the sensitivity axes of the first magnetic detection element, the second magnetic detection element, and the third magnetic detection element is orthogonal to a first magnetic field that is generated around the first busbar when a current flows in the first busbar,
wherein the processing circuit is configured to calculate at least one of I1, I2, and I3 that satisfy: I2∝(d−f)V1+(f−b)V2+(b−d)V3, I3∝(c−e)V1+(e−a)V2+(a−c)V3, and I1=−(I2+I3), from linear equations with three unknowns: V1=aI2+bI3+Bex, V2=cI2+dI3+Bex, and V3=eI2+fI3+Bex, where I1 is a current value of a current flowing in the first busbar, I2 is a current value of a current flowing in the second busbar, I3 is a current value of a current flowing in the third busbar, V1 is an output value of the first magnetic detection element, V2 is an output value of the second magnetic detection element, V3 is an output value of the third magnetic detection element, and Bex is an output component caused by a uniform external magnetic field.

2. The current sensor according to claim 1, wherein three-phase AC currents flow in each of the first busbar, the second busbar, and the third busbar.

3. The current sensor according to claim 1, wherein the first magnetic detection element, the second magnetic detection element, and the third magnetic detection element are mounted on a single chip.

4. The current sensor according to claim 3, wherein the processing circuit is mounted on the single chip.

5. The current sensor according to claim 1, wherein the first busbar, the second busbar, and the third busbar are arranged side by side in a first direction with gaps therebetween.

6. The current sensor according to claim 5, wherein the first magnetic detection element, the second magnetic detection element, and the third magnetic detection element are arranged along a virtual plane that is orthogonal to the three busbars while extending in the first direction and a second direction that is orthogonal to the first direction.

7. The current sensor according to claim 5, wherein the first busbar, the second busbar, and the third busbar are arranged side by side in an end to end configuration with each other.

8. The current sensor according to claim 1, wherein the sensitivity axes of the first magnetic detection element, the second magnetic detection element, and the third magnetic detection element face a same direction as each other.

9. The current sensor according to claim 1, wherein the first magnetic field generated around the first busbar causes each of the first magnetic detection element, the second magnetic detection element, and the third magnetic detection element to output a value of zero.

10. The current sensor according to claim 1, wherein each of the first magnetic detection element, the second magnetic detection element, and the third magnetic detection element has a bridge circuit of Wheatstone bridge type that comprises a plurality of Tunnel Magneto Resistance (TMR) elements.

11. The current sensor according to claim 1, wherein the processing circuit includes three differential amplifier circuits respectively connected to the first magnetic detection element, the second magnetic detection element, and the third magnetic detection element.

12. The current sensor according to claim 11, wherein the processing circuit further includes three inverting summing amplifier circuits and four inverting amplifier circuits.

13. The current sensor according to claim 1, wherein coefficients a through f are calibration coefficients of the current sensor.

14. A current sensor comprising:
a first busbar, a second busbar, and a third busbar;
a first magnetic detection element, a second magnetic detection element, and a third magnetic detection element that each have sensitivity axes that are parallel to one another; and
a processing circuit that is electrically connected to each of the first magnetic detection element, the second magnetic detection element, and the third magnetic detection element,
wherein each of the first, second and third magnetic detection elements is arranged such that each of the sensitivity axes is orthogonal to a first magnetic field that is generated around the first busbar when a current flows in the first busbar,
wherein the processing circuit is configured to calculate at least one of I1, I2, and I3 that satisfy: I2∝(d−f)V1+(f−b)V2+(b−d)V3, I3∝(c−e)V1+(e−a)V2+(a−c)V3, and I1=−(I2+I3), from linear equations with three unknowns: V1=aI2+bI3+Bex, V2=cI2+dI3+Bex, and V3=eI2+fI3+Bex,
where I1 is a current value of a current flowing in the first busbar, I2 is a current value of a current flowing in the second busbar, I3 is a current value of a current flowing in the third busbar, V1 is an output value of the first magnetic detection element, V2 is an output value of the second magnetic detection element, V3 is an output value of the third magnetic detection element, and Bex is an output component caused by a uniform external magnetic field.

15. The current sensor according to claim 14, wherein the first magnetic detection element, the second magnetic detection element, and the third magnetic detection element are arranged relative to the first, second and third busbars with gaps therebetween.

16. The current sensor according to claim 14, wherein coefficients a through f are calibration coefficients of the current sensor.

17. The current sensor according to claim 14, wherein the processing circuit includes three differential amplifier circuits respectively connected to the first magnetic detection element, the second magnetic detection element, and the third magnetic detection element.

18. The current sensor according to claim 17, wherein the processing circuit further includes three inverting summing amplifier circuits and four inverting amplifier circuits.

19. The current sensor according to claim 14, wherein the first magnetic detection element, the second magnetic detection element, the third magnetic detection element and the processing circuit are mounted on a single chip.

20. The current sensor according to claim 14, wherein the first busbar, the second busbar, and the third busbar are arranged side by side in a first direction with gaps therebetween.
